(19) United States
(12) Patent Application Publication
(10) Pub. No.: US 2018/0062059 A1
(43) Pub. Date: Mar. 1, 2018

(54) LIGHT-EMITTING MODULE, LIGHTING APPARATUS FOR MOBILE OBJECT, AND MOBILE OBJECT

(71) Applicant: PANASONIC INTELLECTUAL PROPERTY MANAGEMENT CO., LTD., Osaka (JP)

(72) Inventor: Masashi KICHIMA, Niigata (JP)

(73) Assignee: PANASONIC INTELLECTUAL PROPERTY MANAGEMENT CO., LTD., Osaka (JP)

(21) Appl. No.: 15/673,959

(22) Filed: Aug. 10, 2017

(30) Foreign Application Priority Data
Aug. 26, 2016 (JP) 2016-166301

(51) Int. Cl. H01L 33/64; H01L 33/50; H01L 33/62; H01L 23/00; F21V 29/76; F21S 8/10; F21V 23/06

(52) U.S. Cl. CPC H01L 33/647; H01L 2224/14519; H01L 33/62; H01L 24/16; H01L 24/17; H01L 33/642; F21V 29/76; F21S 48/328; F21V 23/06; F21S 48/1104; H01L 2924/12041; H01L 2224/13147; H01L 2224/1316; H01L 2224/13124; H01L 2224/13144; H01L 2224/13139; H01L 2224/13111; H01L 2224/13155; H01L 33/502

(57) ABSTRACT

A light-emitting module is provided. The light-emitting module includes an insulating substrate. The insulating substrate includes a mounting surface, a rear surface, and a through hole that passes from the mounting surface to the rear surface. A light-emitting element is on the mounting surface. A thermal conductor is disposed in the through hole in contact with an inner wall of the insulating substrate defined by the through hole. The thermal conductor includes a mounting-side end face thermally connected to the light-emitting element, a rear-side end face, and a displacement suppressing portion that suppresses displacement of the thermal conductor in a direction from the rear surface to the mounting surface. thermal conductor. The rear-side end, in a cross-section parallel to the rear surface of the insulating surface, is larger in surface area than the mounting-side end, in a cross-section parallel to the mounting surface of the insulating substrate.

### CROSS REFERENCE TO RELATED APPLICATION

This application claims the benefit of priority of Japanese Patent Application Number 2016-166301 filed on Aug. 26, 2016, the entire content of which is hereby incorporated by reference.

### BACKGROUND

1. Technical Field

The present disclosure relates to a light-emitting module including a thermal conductor, a lighting apparatus for a mobile object which includes the light-emitting module, and a mobile object including the light-emitting module.

2. Description of the Related Art

Conventionally, a configuration in which electronic components such as a light-emitting element, a transistor, etc., are mounted on an insulating substrate such as a printed circuit board is used in electronic devices. Along with an increase in power and a decrease in size of electronic devices, there is a possibility of problems of decreased function, breakdown, etc, due to heat generated in electronic components. In order to solve such problems, a configuration in which a through hole is formed in an insulating substrate, and a thermal conductor having a high thermal conductivity is disposed in the through hole has been proposed (for example, Japanese Unexamined Patent Application Publication No. 2014-99544). In an attempt to solve the above-described problems, Japanese Unexamined Patent Application Publication No. 2014-99544 discloses guiding heat generated in an electronic component to a heat dissipator such as a heat sink, via a thermal conductor.

### SUMMARY

According to the disclosure of Japanese Unexamined Patent Application Publication No. 2014-99544, a through hole having a constant diameter is formed in an insulating substrate in the thickness direction of the insulating substrate, and a cylindrical thermal conductor is inserted in the through hole, thereby guiding heat generated in an electronic component disposed on one of main surfaces of the insulating substrate to a heat dissipator disposed on the other of the main surfaces of the insulating substrate, via the thermal conductor.

However, according to the disclosure of Japanese Unexamined Patent Application Publication No. 2014-99544, there is a possibility that the thermal conductor could detach from the insulating substrate. In particular, in the case where an electronic device is used in a mobile object or the like, detachment of a thermal conductor is promoted by vibrations generated when the mobile object moves.

The present disclosure has been conceived to solve such a problem. An object of the present disclosure is to suppress detachment of a thermal conductor in a light-emitting module including the thermal conductor, a lighting apparatus for a mobile object which includes the light-emitting module, and a mobile object including the light-emitting module.

In order to solve the above-described problem, an aspect of a light-emitting module according to the present disclosure includes: an insulating substrate including a mounting surface, a rear surface, and a through hole that passes from the mounting surface to the rear surface; a light-emitting element on the mounting surface; and a thermal conductor disposed in the through hole in contact with an inner wall of the insulating substrate defined by the through hole, wherein the thermal conductor includes a mounting-side end face thermally connected to the light-emitting element, a rear-side end face, and a displacement suppressing portion that suppresses displacement of the thermal conductor in a direction from the rear surface to the mounting surface, the thermal conductor has a rear-side end and a mounting-side end, and the rear-side end, in a cross-section parallel to the rear surface of the insulating substrate, is larger in surface area than the mounting-side end, in a cross-section parallel to the mounting surface of the insulating substrate.

In addition, in order to solve the above-described problem, an aspect of a lighting apparatus for a mobile object according to the present disclosure includes the above-described light-emitting module.

In addition, in order to solve the above-described problem, an aspect of a mobile object according to the present disclosure includes a headlight that includes the above-described lighting apparatus for a mobile object.

According to the present disclosure, in a light-emitting module including a thermal conductor, and in a lighting apparatus for a mobile object which includes the light-emitting module, and a mobile object including the light-emitting module, it is possible to suppress detachment of the thermal conductor.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a perspective view which schematically illustrates external appearance of the light-emitting module according to Embodiment 1;

FIG. 2 is a top view which schematically illustrates external appearance of the light-emitting module according to Embodiment 1;

FIG. 3 is a cross-sectional diagram which illustrates a configuration of a main portion of the light-emitting module according to Embodiment 1;

FIG. 4 is a cross-sectional diagram which illustrates a configuration of the insulating substrate according to Embodiment 1;

FIG. 5 is an external perspective view which illustrates a shape of the thermal conductor according to Embodiment 1;

FIG. 6A is a cross-sectional diagram which illustrates a configuration of the thermal conductor and the insulating substrate according to Modification 1 of Embodiment 1;

FIG. 6B is a cross-sectional diagram which illustrates a configuration of the thermal conductor and the insulating substrate according to Modification 2 of Embodiment 1;

FIG. 6C is a cross-sectional diagram which illustrates a configuration of the thermal conductor and the insulating substrate according to Modification 3 of Embodiment 1;

FIG. 6D is a cross-sectional diagram which illustrates a configuration of the thermal conductor and the insulating substrate according to Modification 4 of Embodiment 1;

FIG. 6E is a cross-sectional diagram which illustrates a configuration of the thermal conductor and the insulating, substrate according to Modification 5 of Embodiment 1;

FIG. 6F is a cross-sectional diagram which illustrates a configuration of the thermal conductor and the insulating substrate according to Modification 6 of Embodiment 1;

FIG. 6G is a cross-sectional diagram which illustrates a configuration of the thermal conductor and the insulating substrate according to Modification 7 of Embodiment 1;

FIG. 6H is a cross-sectional diagram which illustrates a configuration of the thermal conductor and the insulating substrate according to Modification 8 of Embodiment 1;

FIG. 7 is a top view which illustrates a configuration of the thermal conductor and the insulating substrate according to Modification 9 of Embodiment 1;

FIG. 8 is a perspective view which schematically illustrates external appearance of the light-emitting module according to Embodiment 2;

FIG. 9 is a top view which schematically illustrates external appearance of the light-emitting module according to Embodiment 2;

FIG. 10 is a cross-sectional diagram which illustrates a configuration of a main portion of the light-emitting module according to Embodiment 2;

FIG. 11 is a cross-sectional diagram which illustrates a configuration of a main portion of the light-emitting module according to Embodiment 3;

FIG. 12 is a cross-sectional view which illustrates a configuration of a main portion of the lighting apparatus for a mobile object according to Embodiment 4;

FIG. 13 is a cross-sectional view which illustrates a configuration of a main portion of the lighting apparatus for a mobile object according to Embodiment 5; and

FIG. 14 is an external view of the mobile object according to a modification example.

### DETAILED DESCRIPTION OF THE EMBODIMENTS

Hereinafter, embodiments of the present disclosure shall be described with reference to the drawings. It should be noted that each of the embodiments described below shows a specific example of the present disclosure. Thus, the numerical values, shapes, materials, structural components, the disposition and connection of the structural components, and others described in the following embodiments are mere examples, and do not intend to limit the present disclosure. Furthermore, among the structural components in the following embodiments, components not recited in the independent claims which indicate the broadest concepts of the present disclosure are described as arbitrary structural components.

In addition, each of the diagrams is a schematic diagram and thus is not necessarily strictly illustrated. In each of the diagrams, substantially the same structural components are assigned with the same reference signs, and. redundant descriptions will be omitted or simplified.

### Embodiment 1

### 1-1. Overall Configuration

The following describes an overall configuration of light-emitting module 1 according to Embodiment 1, with reference to the drawings.

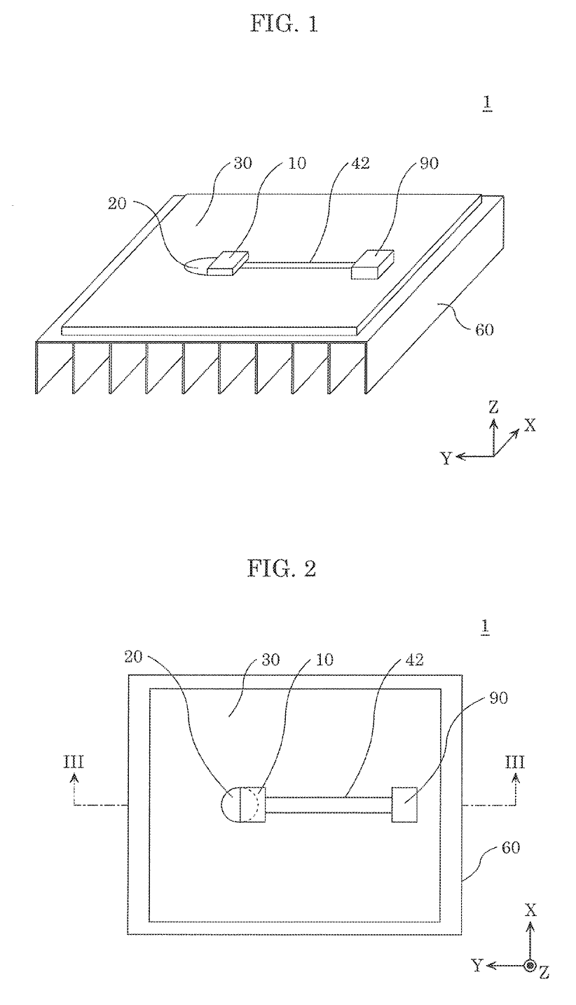

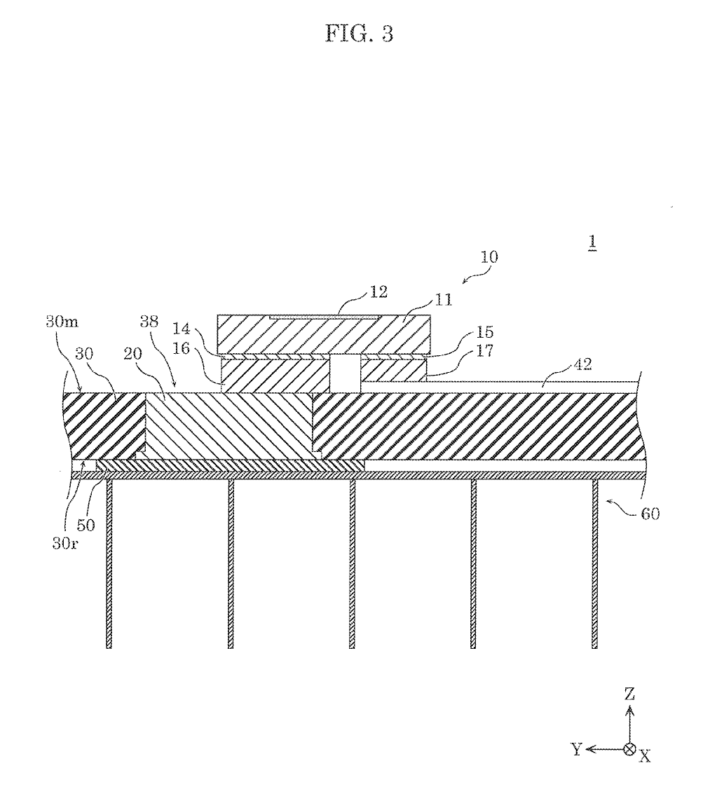

FIG. 1 and FIG. 2 are a perspective view and a top view, respectively, each of which schematically illustrates external appearance of light-emitting module 1 according to the present embodiment. FIG. 3 is a cross-sectional view which illustrates a configuration of a main portion of light-emitting module 1 according to the present embodiment. FIG. 3 shows a cross-section surface taken along III-III of FIG. 2. In each of the diagrams, the direction parallel to an optical axis of light-emitting module 1 is a Z-axis direction, and the directions perpendicular to the Z-axis direction and orthogonal to each other are an X-axis direction and a Y-axis direction.

Light-emitting module 1 illustrated in FIG. 1 to FIG. 3 is a module which emits light as a result of being supplied with power. Light-emitting module 1 includes light-emitting element 10, thermal conductor 20, and insulating substrate 30. According to the present embodiment, light-emitting module 1 further includes terminal 90 and conductor pattern 42 as illustrated in FIG. 1 and FIG. 2. In addition, light-emitting module 1 further includes connection component 50 and heat dissipator 60 as illustrated in FIG. 3.

Light-emitting element 10 is an element which emits light as a result of being supplied with power. Light-emitting element 10 generates heat with emission of light. Light-emitting element 10 is a package including, for example, a light emitting diode (LED) chip, a mounting board, etc. It should be noted that light-emitting element 10 is not limited to the above-described package. For example, light-emitting element 10 may include a semiconductor laser element, or an organic electro luminescence (EL).

Light-emitting element 10 according to the present embodiment includes main body 11, phosphor 12, heat dissipation pad 14, and electrode pad 15, as illustrated in FIG. 3. Main body 11 includes an LED chip, a mounting board, etc. An example of the LED chip to be used includes an LED chip which emits blue light. Phosphor 12 is a wavelength conversion element disposed on a light-exit-surface side of the LED chip. An example of phosphor 12 to be used includes a yellow phosphor which converts a portion of blue light emitted by the LED chip into yellow light. In this manner, light-emitting element 10 is capable of emitting white light which is mixed light of blue light and yellow light.

Heat dissipation pad 14 is a heat dissipation component for dissipating heat generated in light-emitting element 10. Heat dissipation pad 14 is farmed of a material which is relatively high in thermal conductivity, such as copper. In addition, heat dissipation pad 14 is thermally and mechanically connected to thermal conductor 20 via joint component 16. In this manner, it is possible to more reliably conduct heat generated in light-emitting element 10 to thermal conductor 20. Joint component 16 is a component which joins heat dissipation pad 14 and thermal conductor 20. Examples of a material to form

joint component 16 include a metal such as solder, copper, iron, aluminum, gold, silver, tin, nickel, etc., and an alloy of such metals.

Electrode pad 15 is an electrode for supplying power to light-emitting element 10. Electrode pad 15 is formed of, for example, an electrically conductive material such as copper. In addition, electrode pad 15 is electrically and mechanically connected to conductor pattern 42 via joint component 17. Joint component 17 is a component which joins electrode pad 15 and conductor pattern 42. Examples of a material to form joint component 17 include a metal such as solder, copper, iron, aluminum, gold, silver, tin, nickel, etc., and an alloy of such metals.

Insulating substrate 30 is a substrate including mounting surface 30m which is one of main surfaces, and rear surface 30r which is the other of main surfaces. Insulating substrate 30 is provided with through hole 38 that passes through insulating substrate 30 from mounting surface 30m to rear surface 30r. Light-emitting element 10 is mounted on insulating substrate 30. In addition, thermal conductor 20 is inserted into through hole 38 of insulating substrate 30. According to the present embodiment, through hole 38 has a cylindrical shape.

For example, a glass epoxy substrate can be used as insulating substrate 30. It should be noted that the material to form insulating substrate 30 only needs to a material having electrical insulation property, and may be a glass woven fabric, a glass non-woven fabric, a glass composite material, phenolic paper, an epoxy resin, a ceramic, etc. The following describes a shape of insulating substrate 30 in detail with reference to FIG. 4 in addition to FIG. 1 to FIG. 3.

FIG. 4 is a cross-sectional diagram which illustrates a configuration of insulating substrate 30 according to the present embodiment. FIG. 4 shows only insulating substrate 30 of the cross-sectional view illustrated in FIG. 3.

As illustrated in FIG. 4, insulating substrate 30 includes first opening portion 31 corresponding to an end of through hole 38 on mounting-surface-30m side and second opening portion 32 corresponding to an end of through hole 38 on a rear-surface-30r side. Second opening portion 32 is greater in opening area than first opening portion 31. According to the present embodiment, large-diameter portion 34 having a larger inner diameter than other portions of through hole 38 is formed in inner wall 33 of insulating substrate 30 defined by though hole 38, at an end of inner wall 33 corresponding to second opening portion 32.

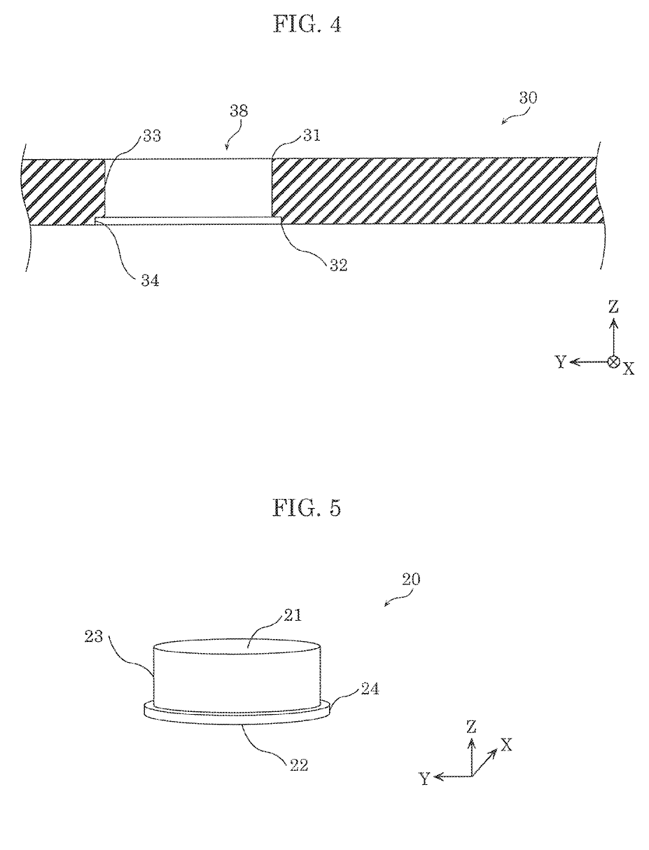

Thermal conductor 20 is a component which is disposed in through hole 38 of insulating substrate 30 and is in contact with inner wall 33. Thermal conductor 20 includes displacement suppressing component 24 which suppresses displacement of thermal conductor 20 in a direction from rear surface 30r to mounting surface 30m. Since thermal conductor 20 includes displacement suppressing component 24, it is possible to suppress detachment of thermal conductor 20 toward mounting surface 30m of insulating substrate 30. Here, a shape of displacement suppressing component 24 of thermal conductor 20, or the like, according to the present embodiment shall be described with reference to FIG. 5.

FIG. 5 is an external perspective view which illustrates a shape of thermal conductor 20 according to the present embodiment.

As illustrated in FIG. 5, thermal conductor 20 according to the present embodiment has a cylindrical shape. More specifically, thermal conductor 20 has a cylindrical shape including end face 21 disposed on the mounting-surface-30m side of insulating substrate 30, end face 22 disposed on the rear-surface-30r side of insulating substrate 30, side face 23, and displacement suppressing component 24 disposed on side face 23 and having a flange shape. The shape of thermal conductor 20 corresponds to the shape of through hole 38 of insulating substrate 30. In addition, according to the present embodiment, displacement suppressing portion 24 is formed on a peripheral edge of the end face on the rear-surface-30r side of thermal conductor 20, and has a flange shape. In other words, displacement suppressing component 24 is a stepped portion which is disposed on an end-face-22 side of thermal conductor 20 and has an outer diameter that increases in a stepwise manner. Displacement suppressing component 24 having a flange shape is disposed on large-diameter portion 34 of insulating substrate 30 illustrated in FIG. 4. According to the present embodiment, it is possible to reliably suppress detachment of thermal conductor 20 from insulating substrate 30, by including displacement suppressing component 24 having a flange shape as described above.

The outer diameter of displacement suppressing component 24 is larger than a minimum value of an inner diameter of inner wall 33. With this configuration, it is possible to suppress detachment of thermal conductor 20 from insulating substrate 30. According to the present embodiment, the outer diameter of displacement suppressing component 24 is larger than the inner diameter of inner wall 33, in the portions other than a portion corresponding to large-diameter portion 34 of inner wall 33. With this configuration, it is possible to suppress displacement of thermal conductor 20 in the direction from rear surface 30r to mounting surface 30m of insulating substrate 30. It should be noted that the shape of thermal conductor 20 is not limited to the cylindrical shape. For example, the shape of thermal conductor 20 may be a circular truncated cone shape in which the outer diameter gradually decreases in the direction from end face 22 to end face 21.

In addition, thermal conductor 20 is thermally connected to light-emitting element 10 on the mounting-surface-30m side of insulating substrate 30. With this configuration, thermal conductor 20 is capable of dissipating heat generated in light-emitting element 10, from an end of thermal conductor 20 on the mounting-surface-30m side to an end of thermal conductor 20 on the rear-surface-30r side. According to the present embodiment, thermal conduct 20 is joined to light-emitting element 10 on mounting surface 30m. In this manner, it is possible to more reliably conduct heat generated in light-emitting element 10 to thermal conductor 20.

In addition, the end of thermal conductor 20 on the rear-surface-30r side is larger in surface area than the end of thermal conductor 20 on the mounting-surface-30m side in a cross-sectional surface parallel to the main surfaces of insulating substrate 30. According to the present embodiment, end face 22 of thermal conductor 20 on the rear-surface-30r side has a larger area than end face 21 of thermal conductor 20 on the mounting-surface-30m side. This configuration makes it easier to dissipate heat transmitted to end face 21 of thermal conductor 20, toward end face 22 of thermal conductor 20, and thus it is possible to facilitate heat dissipation of light-emitting element 10. According to the present embodiment, end face 22 of thermal conductor 20 is thermally connected to heat dissipator 60 via connection component 50, as illustrated in FIG. 3. With this configuration, heat transmitted to thermal conductor 20 is conducted to heat dissipator 60, and thus it is possible to reduce remaining of heat in thermal conductor 20. Accordingly, an increase in the temperature of thermal conductor 20 is suppressed. Therefore, it is possible to improve the heat dissipation efficiency in dissipating heat from light-emitting element 10 to thermal conductor 20.

In addition, as illustrated in FIG. 2, thermal conductor 20 includes a portion which overlaps with at least a portion of light-emitting element 10 in a plan view of insulating substrate 30. In FIG. 2, a peripheral edge of a portion of thermal conductor 20 which overlaps with light-emitting element 10 in a plan view is indicated by a dashed line. In this manner, light-emitting element 10 is disposed above thermal conductor 20, and thus it is possible to reduce the distance between light-emitting element 10 and thermal conductor 20. Accordingly, thermal resistance between light-emitting element 10 and thermal conductor 20 can be reduced. Therefore, it is possible to improve the heat dissipation efficiency in dissipating heat from light-emitting clement 10 to thermal conductor 20.

A material to form thermal conductor 20 only needs to be a material having a higher thermal conductivity than a material which forms an insulating substrate. Examples of such a material to form thermal conductor 20 include copper, iron, aluminum, cold, silver, tin, nickel, solder, plastic with a high thermal conductivity, etc. In addition, a method of manufacturing thermal conductor 20 is not specifically limited. For example, it is possible to form thermal conductor 20 including displacement suppressing component 24, by performing press working in a state in which a cylindrical metal component having an outer diameter less than or equal to an inner diameter of through hole 38 and a height greater than a thickness of insulating substrate 30 is inserted in through hole 38. It should be noted that thermal conductor 20 may be formed by molding, machine processing, etc.

Conductor pattern 42 is a conductor layer disposed on mounting surface 30m of insulating substrate 30. Conductor pattern 42 is electrically connected to electrode pad 15 and terminal 90 of light-emitting element 10. With this configuration, it is possible to supply power from terminal 90 to light-emitting element 10 via conductor pattern 42. In addition, it is possible to dissipate heat. generated in light-emitting element 10, via conductor pattern 42. In addition, according to the present embodiment, conductor pattern 42 and electrode pad 15 of light-emitting element 10 can be joined, and thus it is not necessary to use a bonding wire or the like. Accordingly, it is possible to simplify the processes of mounting light-emitting element 10. It should be noted that, although conductor pattern 42 is disposed on surface 30m according to the present embodiment, it is sufficient to dispose conductor pattern 42 on at least one of mounting surface 30m and rear surface 30r. For example, when conductor pattern 42 is disposed on rear surface 30r, conductor pattern 42 may be connected to light-emitting element 10 via a via wiring that penetrates through insulating substrate 30

Terminal 90 is a terminal for supplying power to light-emitting element 1. Terminal 90 may be a connector capable of connecting a plug for supplying power.

As illustrated in FIG. 3, connection component 50 is a sheet-like component which is disposed between insulating substrate 30 and heat dissipater 60, and thermally connects thermal conductor 20 and heat dissipator 60. A material to form connection component 50 only needs to be a material having a higher thermal conductivity than insulating substrate 30. Examples of a material to form connection component 50 include a metal such as solder, copper, iron, aluminum, gold, silver, tin, nickel, etc., and an alloy of such metals.

Heat dissipator 60 is a component for dissipating heat generated in light-emitting element 10. Heat dissipator 60 is thermally connected to thermal conductor 20. Heat generated in light-emitting element 10 is conducted to heat dissipator 60 via thermal conductor 20. Accordingly, it is possible to conduct heat generated in light-emitting element 10 to heat dissipator 60 via thermal conductor 20, and thus heat dissipation property of light-emitting module 1 can be improved. The configuration of heat dissipator 60 is not specifically limited as long as heat can be dissipated. Heat dissipator 60 may include a plurality of heat dissipation fins as illustrated in FIG. 1 and FIG. 3, for example. In addition, heat dissipator 60 may further include a fan for air-cooling heat dissipator 60.

### 1-2. Conclusion

As described above, light-emitting module 1 according to the present embodiment includes: insulating substrate 30 including mounting surface 30m; rear surface 30r; and through hole 38 that passes from mounting surface 30m to rear surface 30r. Light-emitting module 1 fluffier includes: light-emitting element 10 on mounting surface 30m; and thermal conductor 20 disposed in through hole 38 in contact with inner wall 33 of insulating substrate 30 defined by through hole 38. Thermal conductor 20 includes end face 21 on the mounting-surface-30m side thermally connected to light-emitting element 10, end face 22 on the rear-surface-30r side, and displacement suppressing portion 24 that suppresses displacement of thermal conductor 20 in a direction from rear surface 30r to mounting surface 30m. Thermal conductor 20 has an end on the mounting-surface-30m side and an end on the rear-surface-30r side, and the end n the rear-surface-30r side is larger in surface area than the end on the mounting-surface-30m side in a cross-sectional surface parallel to mounting surface 30m of insulating substrate 30.

As described above, since thermal conductor 20 includes displacement suppressing component 24 in light-emitting module 1, it is possible to suppress detachment of thermal conductor 20 in a direction toward mounting surface 30m of insulating substrate 30. In addition, when end face 22 of thermal conductor 20 on the rear-surface-30r side is covered by heat dissipater 60 or the like, it is also possible to suppress detachment of thermal conductor 20 from insulating substrate 30 in a direction toward rear surface 30r. Accordingly, even when light-emitting module 1 is included by a mobile object or the like, and vibrates with movement of the mobile object, it is also possible to suppress detachment of thermal conductor 20 from light-emitting module 1. In addition, since the end of thermal conductor 20 on the rear-surface-30r side is larger in surface area than the end of thermal conductor 20 on the mounting,-surface-30m side in a cross-sectional surface parallel to the main surfaces of insulating substrate 30, heat transmitted to end face 21 is easily dissipated toward end face 22. Accordingly, it is possible to facilitate heat dissipation of light-emitting element 10.

In addition, in light-emitting module 1 according to the present embodiment, displacement suppressing portion 24 may be formed on a peripheral edge of end face 22 on the rear-surface-30r side of thermal conductor 20, and may have a flange shape.

With this configuration, it is possible to reliably suppress detachment of thermal conductor 20 from insulating substrate 30.

In addition, in light-emitting module 1 according to the present embodiment, displacement suppressing portion 24 may include an outer diameter which is larger than a minimum value of a diameter of inner wall 33 of insulating substrate 30 defined by through hole 38.

In addition, in light-emitting module 1 according to the present embodiment, thermal conductor 20 may be joined to light-emitting element 10 on the mounting-surface-30m side.

With this configuration, it is possible to more reliably conduct heat generated in light-emitting element 10 to thermal conductor 20. Therefore, it is possible to improve the heat dissipation efficiency in dissipating heat from light-emitting element 10 to thermal conductor 20.

In addition, in light-emitting module 1 according to the present embodiment, thermal conductor 20 may include a portion which overlaps with at least a portion of light-emitting element 10 in a plan view of insulating substrate 30.

With this configuration, light-emitting element 10 is disposed above thermal conductor 20, and thus it is possible to reduce the distance between light-emitting element 10 and thermal conductor 20. Accordingly, thermal resistance between light-emitting element 10 and thermal conductor 20 can be reduced. Therefore, it is possible to improve the heat dissipation efficiency in dissipating heat from light-emitting element 10 to thermal conductor 20.

In addition, light-emitting module 1 according to the present embodiment may include conductor pattern 42 disposed at least one of mounting surface 30m and rear surface 30r.

With this configuration, it is possible to supply power to light-emitting element 10 and dissipate heat, generated in light-emitting element. 10, via conductor pattern 42.

In addition, in light-emitting module 1 according to the present embodiment, thermal conductor 20 may be thermally connected. to heat dissipator 60 on end face 22 on the rear-surface-30r side.

With this configuration, it is possible to conduct heat generated in light-emitting element 10 to heat dissipator 60 via thermal conductor 20, and thus the heat dissipation property of light-emitting module 1 can be improved.

In addition, light-emitting module 1 according to the present embodiment may include heat dissipater 60.

With this configuration, it is possible to dissipate heat generated in light-emitting element 10, by heat dissipater 60, and thus the heat dissipation property of light-emitting module 1 can be improved.

(Modification Examples of Embodiment 1)

Next, a modification example of light-emitting module 1 according to Embodiment 1 will be described. The present modification example is different from Embodiment 1 in the shape of the thermal conductor and the insulating substrate of the light-emitting module. The following describes the present modification example with reference to the drawings, focusing on the differences from Embodiment 1.

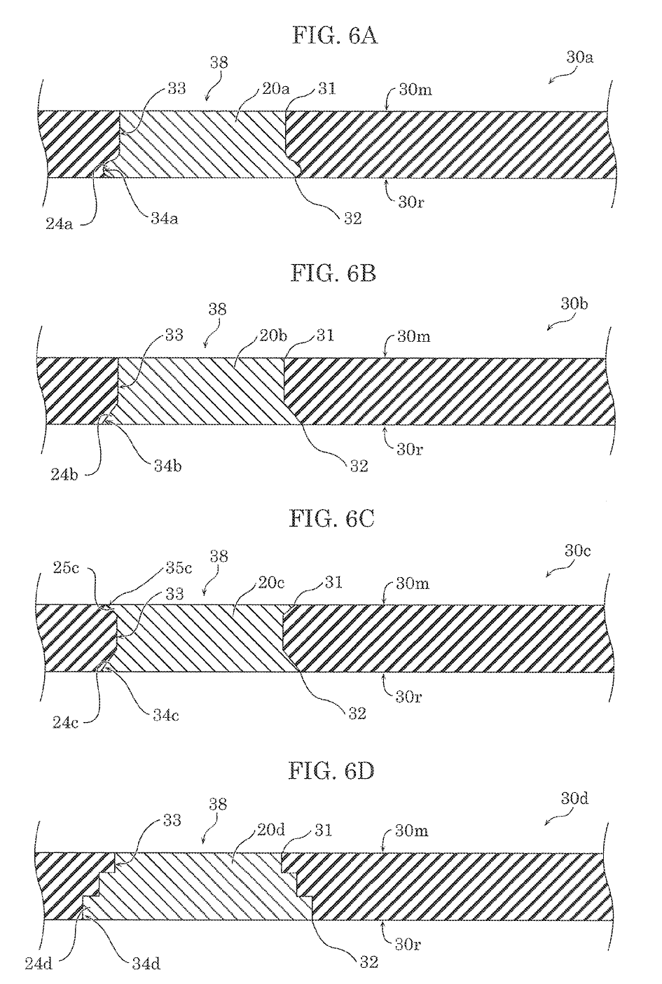

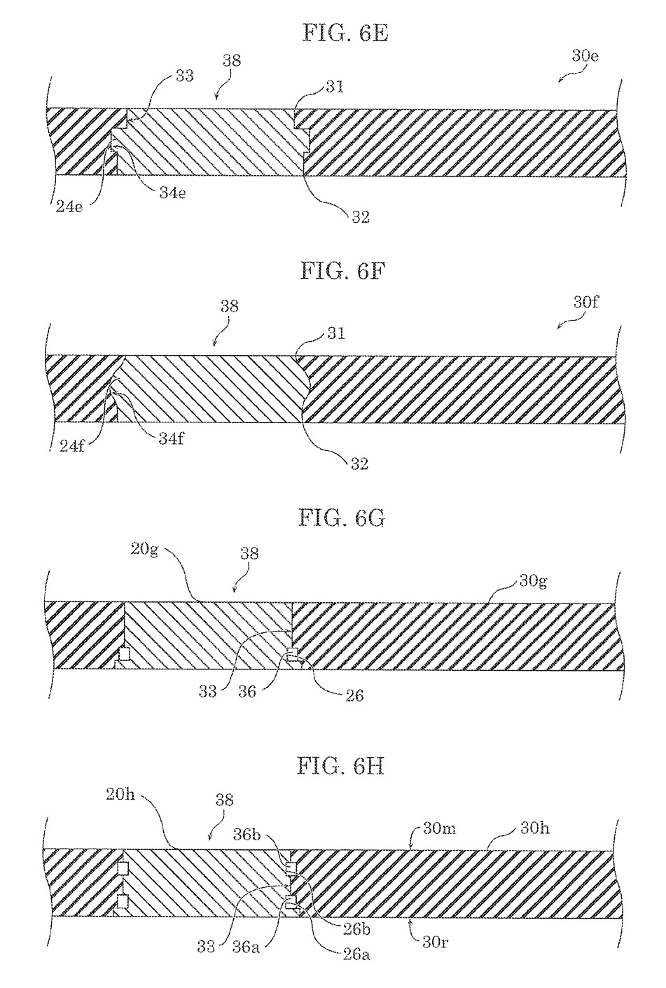

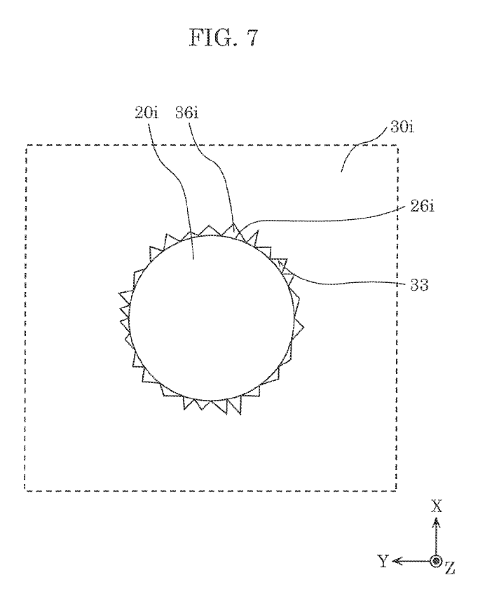

FIG. 6A to FIG. 6H are cross-sectional views illustrating configurations of the thermal conductors and the insulating substrates according to Modifications 1 to 8 of Embodiment 1. In each of the diagrams, a cross-section surface similar to the cross-section surface illustrated in FIG. 3 is illustrated. FIG. 7 is a top view which illustrates a configuration of thermal conductor 20i and insulating substrate 30i according to Modification 9 of Embodiment 1. In FIG. 7, a partially enlarged view of insulating substrate 30i is illustrated. In addition, structural components other than the thermal conductor and the insulating substrate of the light-emitting module according to each of the modification examples each have a configuration similar to a configuration of a corresponding structural component of light-emitting module 1 according to Embodiment 1. Accordingly, illustration is omitted.

Thermal conductor 20a according to Modification 1 illustrated in FIG. 6A includes displacement suppressing component 24a having a flange shape, as with thermal conductor 20 according to Embodiment 1. However, thermal conductor 20a according Modification 1 is different from thermal conductor 20a according to Embodiment 1 in that an outline of the cross-section surface of displacement suppressing component 24a illustrated in FIG. 6A has a curvature. Correspondingly, an outline of the cross-section surface of large-diameter portion 34a of insulating substrate 30a illustrated in FIG. 6A also has a curvature.

The light-emitting module including thermal conductor 20a and insulating substrate 30a which have the above-described configurations also produces advantageous effects same as the advantageous effects produced by light-emitting module 1 according to the above-described Embodiment 1.

Thermal conductor 20b according to Modification 2 illustrated in FIG. 6B includes displacement suppressing component 24b having a flange shape, as with thermal conductor 20 according to Embodiment 1. However, displacement suppressing portion 24b has a tapered shape in which an outer diameter decreases in the direction from rear surface 30r to mounting surface 30m. In other words, thermal conductor 20b includes a tapered shape portion in which an outer diameter of thermal conductor 20 decreases in the direction from rear surface 30r to mounting surface 30m. Correspondingly, large-diameter portion 34b of insulating substrate 30b also has a tapered shape in which a diameter increases in the direction from mounting surface 30m to rear surface 30r.

The light-emitting module including thermal conductor 20b and insulating substrate 301 which have the above-described configurations also produces advantageous effects same as the advantageous effects produced by light-emitting module 1 according to the above-described Embodiment 1.

Thermal conductor 20c according to Modification 3 illustrated in FIG. 6C includes displacement suppressing component 24c having a tapered shape similar to the tapered shape of thermal conductor 20b according to Modification 2. Correspondingly, large-diameter portion 34c of insulating substrate 30c also has a tapered shape in which a diameter increases in the direction from mounting surface 30m to rear surface 30r. Thermal conductor 20c further includes tapered shape portion 25c in which a diameter increases in the direction from rear surface 30r to mounting surface 30m. Correspondingly, insulating substrate 30c further include large-diameter portion 35c having a tapered shape in which an outer diameter increases in the direction from rear surface 30r to the mounting surface 30m.

As described above, thermal conductor 20c further includes a second displacement suppressing portion that suppresses displacement of thermal conductor 20c in a direction from mounting surface 30m to rear surface 30r.

In addition, thermal conductor 20c further includes a second displacement suppressing portion that suppresses displacement of the thermal conductor in a second direction from mounting surface 30m to rear surface 30r, and the second displacement suppressing portion includes a second tapered shape in which the outer diameter of thermal conductor 20c decreases in the second direction from mounting surface 30m to rear surface 30r.

The light-emitting module including thermal conductor 20c and insulating substrate 30c which have the above-described configurations also produces advantageous effects same as the advantageous effects produced by light-emitting module 1 according to the above-described Embodiment 1. Moreover, according to the present modification example, since thermal conductor 20c includes tapered shape portion 25c, displacement of thermal conductor 20c in the direction from mounting surface 30m to rear surface 30r of insulating substrate 30c is suppressed. Thus, according to the present modification example, it is possible to further suppress detachment of thermal conductor 20c from insulating substrate 30c.

Thermal conductor 20d according to Modification 4 illustrated in FIG. 6D includes displacement suppressing component 24d having a flange shape, as with thermal conductor 20 according to Embodiment 1. However, thermal conductor 20d according to Modification 4 is different from thermal conductor 20 in the shape. Displacement suppressing component 24d of thermal conductor 20d. according to Modification 4 has a stepped shape in which an outer diameter decreases in a stepwise manner in the direction from rear surface 30r to mounting surface 30m. In other words, thermal conductor 20d includes a stepped portion in which an outer diameter increases in the direction from mounting surface 30m to rear surface 30r. Correspondingly, insulating substrate 30d includes large-diameter portion 34d having a stepped shape in which an outer diameter increases in the direction from mounting surface 30m to rear surface 30r.

The light-emitting module including thermal conductor 20d and insulating substrate 30d which have the above-described configurations also produces advantageous effects same as the advantageous effects produced by light-emitting module 1 according to the above-described Embodiment 1.

Thermal conductor 20e according to Modification 5 illustrated in FIG. 6E includes displacement suppressing component 24e having a flange shape, as with thermal conductor 20 according to Embodiment 1. However, thermal conductor 20e according to Modification 5 is different from thermal conductor 20 mainly in the position of placement. Displacement suppressing component 24e of thermal conductor 20e according to Modification 5 is disposed at a substantially center portion of insulating substrate 30e in the thickness direction. In other words, displacement suppressing component 24e includes a shape in which an outer diameter of thermal conductor 20e increases and then decreases in the direction from rear surface 30r to mounting surface 30m. In the present modification example, displacement suppressing component 24e has a flange shape, Correspondingly, insulating substrate 30e includes large-diameter portion 34e at a substantially center portion in the thickness direction. In addition, displacement suppressing component 24e of thermal conductor 20e comprises a protrusion between the mounting-side end and the rear-side end, and a first protruding distance of the protrusion on the rear-side end of thermal conductor 20e is less than a second protruding distance of the protrusion on the mounting-side end of thermal conductor 20e.

The light-emitting module including thermal conductor 20e and insulating substrate 30e which have the above-described configurations also produces advantageous effects same as the advantageous effects produced by light-emitting module 1 according to the above-described Embodiment 1. Moreover, according to the present modification example, since thermal conductor 20e includes displacement suppressing component 24e at a substantially center portion in the thickness direction of insulating substrate 30e, displacement of thermal conductor 20e in the direction from mounting surface 30m to rear surface 30r of insulating substrate 30e is suppressed.

Thermal conductor 20f according to Modification 6 illustrated in FIG. 6F includes displacement suppressing component 24f at a substantially center portion in the thickness direction of insulating substrate 30f, as with thermal

conductor 20e according to Modification 5. However, thermal conductor 20f according to Modification 6 is different from thermal conductor 20e according to Modification 5 in that an outline of the cross-section surface of displacement suppressing component 24f illustrated in FIG. 6F has a curvature. Correspondingly, an outline of the cross-section surface of large-diameter portion 34f of insulating substrate 30f illustrated in FIG. 6F also has a curvature.

The light-emitting module including thermal conductor 20f and insulating substrate 30f which have the above-described configurations also produces advantageous effects same as the advantageous effects produced by the light-emitting module including thermal conductor 20e and insulating substrate 30e according to the above-described Modification 5.

Thermal conductor 20g according to Modification 7 illustrated in FIG. 6G is different from thermal conductor 20 according to Embodiment 1 in that thermal conductor 20g according to Modification 7 includes spaced portion 26 which faces inner wall 33 that defines through hole 38 provided in insulating substrate 30g, and is spaced apart from inner wall 33. According to the present modification example, void 36 having an annular shape is formed between annular-shaped spaced portion 26 of thermal conductor 20g and inner wall 33 of insulating substrate 30g. In other words, spaced portion 26 defines void 36 between inner wall 33 and thermal conductor 20g. In this case, with this configuration, it is possible to suppress conducting of heat from thermal conductor 20g to insulating substrate 30g. Accordingly, since an increase in the temperature of insulating substrate 30g is suppressed, it is possible to suppress conducting of heat from insulating substrate 30g to light-emitting element 10 and other electronic components. With this configuration, it is possible to suppress an adverse effect, due to an increase in the temperature of insulating substrate 30g, on light-emitting element 10 and the like. For example, it is possible to suppress a decrease in a light-emitting efficiency of light-emitting element 10 due to an increase in the temperature. A method of forming spaced. portion 26 is not specifically limited. For example, spaced portion 26 may be formed by providing a portion having an outer diameter smaller than the other portion on a surface of thermal conductor 20g which faces insulating substrate 30g. Alternatively, spaced portion 26 may be formed by providing a portion having an inner diameter larger than the other portion on inner wall 33 of insulating substrate 30g.

Thermal conductor 20h according to Modification 8 illustrated in FIG. 6H is different from thermal conductor 20g according to Modification 7 in that thermal conductor 20h according to Modification 8 includes two spaced portions 26a and 26b. According to the present modification example, voids 36a and 36b each having an annular shape are formed between annular-shaped spaced portions 26a and 26b of thermal conductor 20h and inner wall 33 of insulating substrate 30h. With this configuration, it is possible to further suppress conducting of heat from thermal conductor 20h to insulating substrate 30h.

Thermal conductor 20i according to Modification 9 illustrated in FIG. 7 includes spaced portion 26i, as with each of the thermal conductors according to Modifications 7 and 8. However, thermal conductor 20i according to Modification 9 is different from each of the thermal conductors according to Modifications 7 and 8 in that spaced portion 26i does not have an annular shape. In the present modification example, spaced portion 26i and void 36i are randomly provided by forming unevenness on inner wall 33 of insulating substrate 30i. According to thermal conductor 201 and insulating substrate 30i according to the present modification example as well, it is possible to suppress conducting of heat from thermal conductor 20i to insulating substrate 30i as with Modifications 7 and 8. A method of manufacturing thermal conductor 30i according to the present modification example is not specifically limited. For example, insulating substrate 30i may be manufactured by forming, after forming a cylindrical through hole, unevenness on an inner wall that defines the through hole.

### Embodiment 2

The following describes a light-emitting module according to Embodiment 2. The light-emitting module according to the present embodiment is different from light-emitting module 1 according to Embodiment 1 in a configuration of the thermal conductor and an electrical connection configuration between the light-emitting element and the terminal. The following describes a light-emitting module according to the present embodiment with reference to the drawings, focusing on differences from light-emitting module 1 according to Embodiment 1.

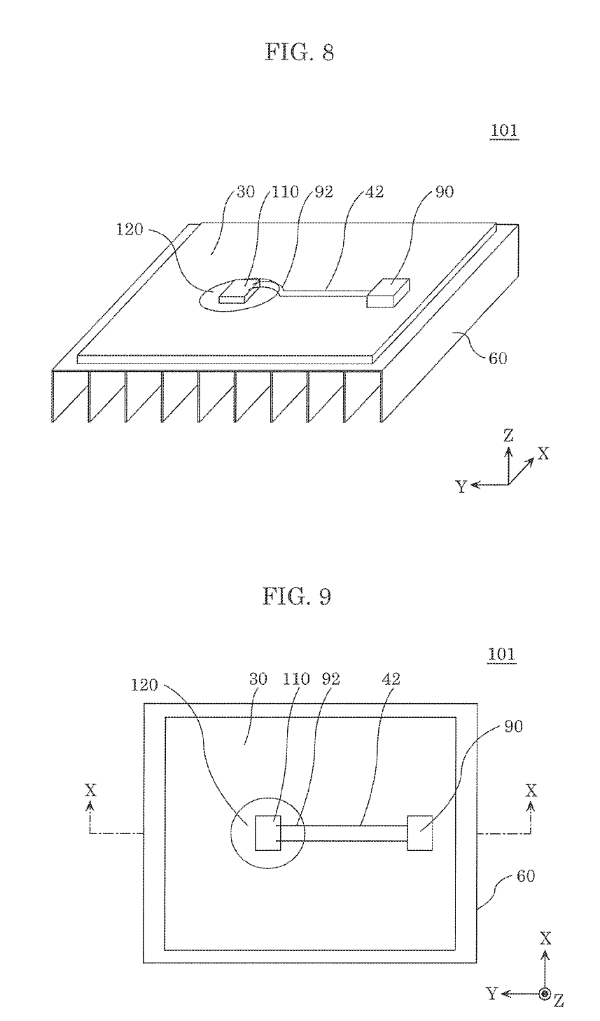

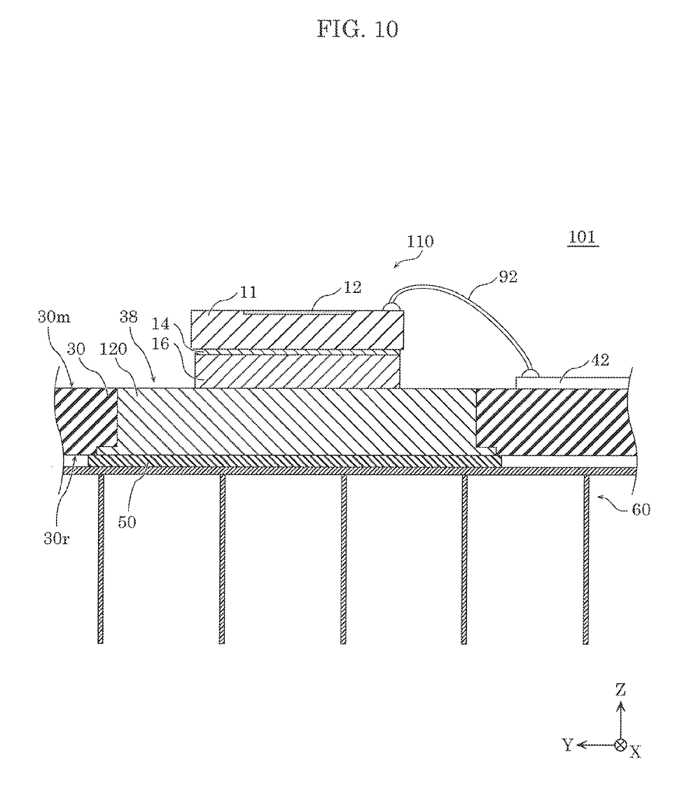

FIG. 8 and FIG. 9 are a perspective view and a top view, respectively, each of which schematically illustrates external appearance of light emitting module 101 according to the present embodiment. FIG. 10 is a cross-sectional view which illustrates a configuration of a main portion of light-emitting module 101 according to the present embodiment. FIG. 10 shows a cross-section surface taken along X-X of FIG. 9.

As illustrated in FIG. 8 and FIG. 9, light-emitting module 101 according to the present embodiment includes light-emitting element 110, thermal conductor 120, insulating substrate 30, terminal 90, conductor pattern 42, and heat dissipator 60, in the same manner as light-emitting module 1 according to Embodiment 1. In addition, light-emitting module 101 further includes connection component 50 as illustrated in FIG. 10. Furthermore, light-emitting module 101 according to the present embodiment further includes wire 92.

Wire 92 is a conductor wire for transmitting power supplied to terminal 90, to light-emitting element 10. According to the present embodiment, wire i.s a bonding wire, and includes one end bonded to an electrode pad (not illustrated) of light-emitting element 110 and the other end bonded to conductor pattern 42. According to the present embodiment, the electrode pad (not illustrated) of light-emitting element 110 is disposed on an upper surface of light-emitting element 110 in FIG. 10, that is, on a surface opposite to a surface on which heat dissipation pad 14 of light-emitting element 110 is disposed. With this, according to the present embodiment, wire 92 electrically connects between the electrode pad of light-emitting element 110 and conductor pattern 42.

As illustrated in FIG. 9, in light-emitting module 101 according to the present embodiment, light-emitting element 110 as a whole overlaps with thermal conductor 120 in a plan view of insulating substrate 30. In other words, light-emitting element 110 as a whole is disposed above thermal conductor 120. In addition, as illustrated in FIG. 10, heat dissipation pad 14 is formed on light-emitting element 110 to cover substantially the entirety of a surface of light-emitting element 110 facing thermal conductor 120, and substantially the entire surface of heat dissipation pad 14 facing thermal conductor 120 is thermally and mechanically connected to thermal conductor 120 by joint component 16.

As described above, according to the present embodiment, it is possible to enlarge a contacting area between thermal conductor 120 and joint component 16, and a contacting area between joint component 16 and heat dissipation pad 14. With this configuration, it is possible to improve the heat dissipation efficiency from light-emitting element 110 to thermal conductor 120.

### Embodiment 3

The following describes a light-emitting module according to Embodiment 3. The light emitting module according to the present embodiment is different from light-emitting module 1 according to Embodiment 1 in that the light emitting module according to the present embodiment further includes a configuration for improving the heat dissipation efficiency of dissipating heat from the thermal conductor. The following describes a configuration of the light-emitting according to the present embodiment with reference to the drawings, focusing on differences from light-emitting module 1 according to Embodiment 1.

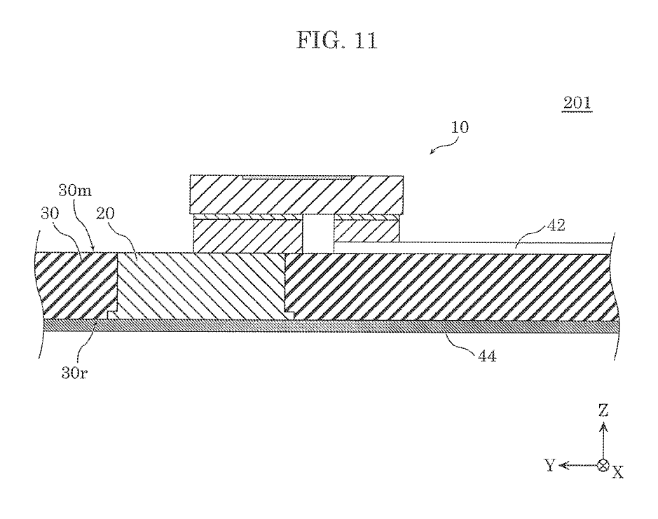

FIG. 11 is a cross-sectional view which illustrates a configuration of a main portion of light-emitting module 201 according to the present embodiment. In FIG. 11, a cross-section surface of light-emitting module 201 similar to the cross-section surface illustrated in FIG. 3 is illustrated.

As illustrated in FIG. 11, light-emitting module 201 according to the present embodiment further includes heat equalizing layer 44, in addition to the components included in light-emitting module 1 according to Embodiment 1. Heat equalizing layer 44 is disposed on rear surface 30r of insulating substrate 30. Although not illustrated in FIG. 11, light-emitting module 201 may include, below heat equalizing layer 44 in FIG. 11, connection component 50 and heat dissipator 60 as with light-emitting module 1 according to Embodiment 1.

Heat equalizing layer 44 is a layer thermally connected to thermal conductor 20 and extending on rear surface 30r of insulating substrate 30. Heat equalizing layer 44 is higher in the thermal conductivity than insulating substrate 30. As a result of including such heat equalizing layer 44, heat conducted from light-emitting element 10 to thermal conductor 20 diffuses inside heat equalizing layer 44 in light-emitting module 201. Accordingly, it is possible to facilitate dissipation of heat of thermal conductor 20. In addition, it is possible to further facilitate dissipation of heat of thermal conductor 20, by connecting heat dissipator 60 to heat equalizing layer 44 via connection component 50 or the like.

### Embodiment 4

The following describes a lighting apparatus for a mobile object according to Embodiment 4. A lighting apparatus for a mobile object according to the present embodiment is a lighting apparatus which is installed on a mobile object, and includes the light-emitting module according to any one of Embodiments 1 to 3. The lighting apparatus for a mobile object according to the present embodiment has a feature in an installation manner of the light-emitting module. The following describes a lighting apparatus for a mobile object according to the present embodiment, with reference to the drawings.

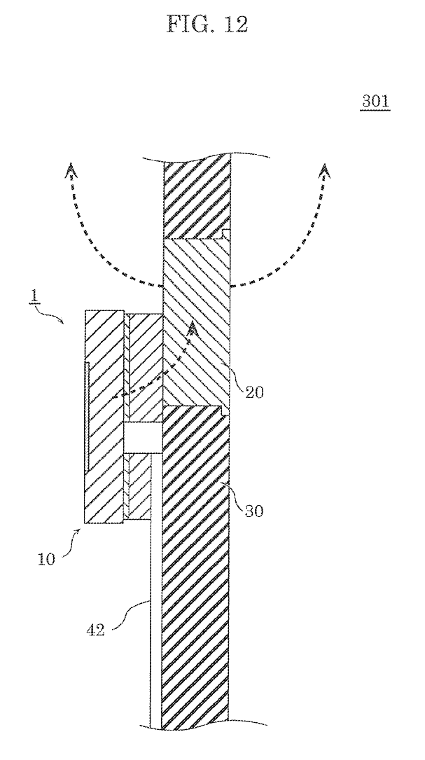

FIG. 12 is a cross-sectional view which illustrates a configuration of a main portion of lighting apparatus for a mobile object 301 according to the present embodiment. In FIG. 12, a cross-section surface of light-emitting module 1 included by lighting apparatus for a mobile object 301 similar to the cross-section surface illustrated in. FIG. 3 is illustrated. In FIG. 12, the up and down directions correspond to the vertical direction and the upper side in FIG. 12 corresponds to the upper side of the vertical direction.

As illustrated in FIG. 12, lighting apparatus for a mobile object 301 according to the present embodiment includes light-emitting module 1. Although not illustrated in FIG. 12, light-emitting module 1 may include connection component 50 and heat dissipator 60. In addition, although not illustrated in FIG. 12, lighting apparatus for a mobile object 301 includes a jig or the like for securing a position and an orientation of light-emitting module 1.

In lighting apparatus for a mobile object 301, thermal conductor 20 is positioned higher in the vertical direction of mobile object than light-emitting element 10. Lighting apparatus for a mobile object 301 is attached to a mobile object while maintaining this state. With this configuration, when thermal conductor 20 is heated by heat conducted from light-emitting element 10, an air temperature surrounding thermal conductor 20 increases. The air with the increased temperature decreases in density, and thus moves upward in the vertical direction due to buoyant force (see the dashed arrows illustrated in FIG. 12). On the other hand, light-emitting element 10 is positioned lower in the vertical direction than thermal conductor 20, and thus it is possible to suppress the air with the increased temperature reaching an area surrounding light-emitting element 10. Accordingly, since an increase in the air temperature surrounding light-emitting element 10 can be suppressed, it is possible to suppress an increase in the temperature of light-emitting element 10.

It should be noted that, although lighting apparatus for a mobile object 301 includes light-emitting module 1 according to the present embodiment, lighting apparatus for a mobile object 301 may include a light-emitting module other than light-emitting module 1. For example, lighting apparatus for a mobile object 301. may include the light-emitting module according to Embodiment 2 or Embodiment 3.

### Embodiment 5

The following describes a lighting apparatus for a mobile object according to Embodiment 5. The lighting apparatus for a mobile object according to the present embodiment is different from lighting apparatus for a mobile object 301 according to Embodiment 4 in that a flow path for a gas flowing around the light-emitting module is formed, and that a relative position of thermal conductor 20 relative to light-emitting element 10 is not limited. The following describes a lighting apparatus for a mobile object according to the present embodiment, with reference to the drawings.

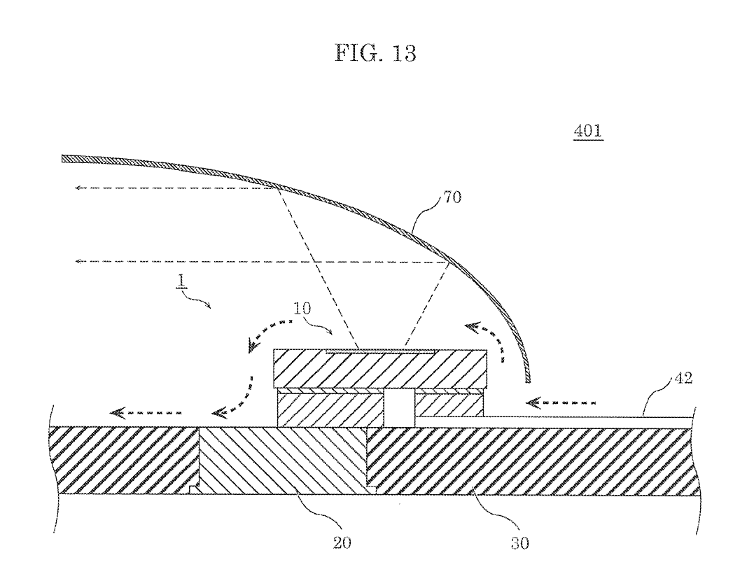

FIG. 13 is a cross-sectional view which illustrates a configuration of a main portion of lighting apparatus for a mobile object 401 according to the present embodiment. In FIG. 13, a cross-section surface of light-emitting module 1 included by lighting apparatus for a mobile object 401 similar to the cross-section surface illustrated in FIG. 3 is illustrated.

Lighting apparatus for a mobile object 401 according to the present embodiment includes reflector 70 in addition to light-emitting module 1.

Reflector 70 is an optical element which reflects light emitted from light-emitting module 1. Reflector 70 may have a reflective surface of a paraboloidal shape. Reflector 70 may collect divergent tight emitted from light-emitting module 1 disposed in proximity to a focal point of the reflective surface of the paraboloidal shape.

According to the present embodiment, reflector 70 serves as a flow path for flowing a gas around the light-emitting module. For example, when a fan or the like is used to flow air from the right side toward the left side of FIG. 13, a flow path as indicated by dashed arrows in FIG. 13 is formed by light-emitting module 1 and reflector 70. Here, thermal conductor 20 of light-emitting module 1 is positioned further downstream along the flow path than light-emitting element 10. With this configuration, even when the temperature of air surrounding thermal conductor 20 to which heat from light-emitting element 10 is conducted increases, it is possible to suppress the air with the increased temperature reaching light-emitting element 10 positioned upstream in the flow path. Accordingly, since an increase in the air temperature surrounding light-emitting element 10 can be suppressed, it is possible to suppress an increase in the temperature of light-emitting element 10.

### Other Modifications, etc.

The light-emitting module and the lighting apparatus for a mobile object according to the present disclosure have been described above, based on the embodiments and modification examples thereof. However, the present disclosure is not limited to the above-described embodiments.

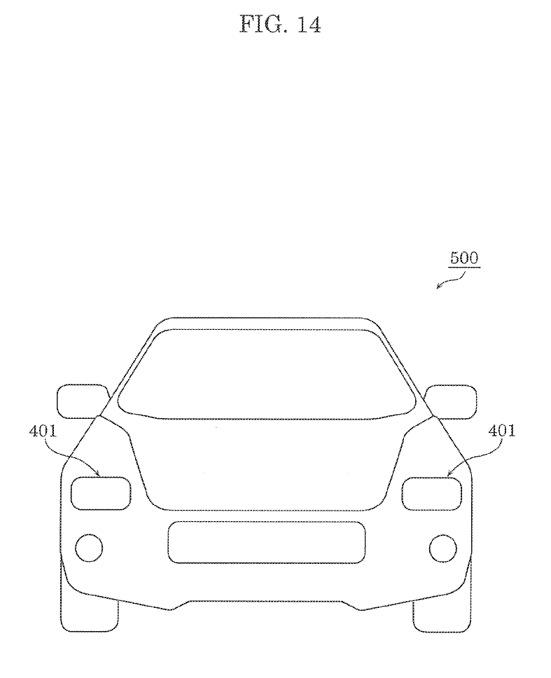

For example, the light-emitting module and the lighting apparatus for a mobile object according to the above-described embodiments and modification examples can be used for various devices. For example, an aspect of the present disclosure can be implemented as mobile object 500 as illustrated in FIG. 14. FIG. 14 is an external view of mobile object 500 according to the present modification example. Mobile object 500 illustrated in FIG. 14 includes, for example, a headlight which includes lighting apparatus for a mobile object 401 according to Embodiment 5. It should be noted that the lighting apparatus for a mobile object used as a headlight or the like of mobile object 500 is not limited to lighting apparatus for a mobile object 401 according to Embodiment 5. For example, the lighting apparatus for a mobile object used as a headlight or the like of mobile object 500 may be a lighting apparatus for a mobile object which includes the light-emitting module according to Embodiment 1, Embodiment 2, or Embodiment 3, or the light emitting module according to the modification examples thereof, such as lighting apparatus for a mobile object 301 according to Embodiment 4.

Moreover, embodiments obtained through various modifications to the embodiments and modifications which may be conceived by a person skilled in the art as well as embodiments realized by arbitrarily combining the structural components and functions of the embodiments and modifications without materially departing from the spirit of the present disclosure are. included in the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A light-emitting module, comprising:
an insulating substrate including a mounting surface, a rear surface, and a through hole that passes from the mounting surface to the rear surface;
a light-emitting element on the mounting surface; and
a thermal conductor disposed in the through hole in contact with an inner wall of the insulating substrate defined by the through hole,
wherein the thermal conductor includes a mounting-side end face thermally connected to the light-emitting element, a rear-side end face, and a displacement suppressing portion that suppresses displacement of the thermal conductor in a direction from the rear surface to the mounting surface,
the thermal conductor has a rear-side end and a mounting-side end, and
the rear-side end, in a cross-section parallel to the rear surface of the insulating substrate, is larger in surface area than the mounting-side end, in a cross-section parallel to the mounting surface of the insulating substrate. The light-emitting module according to claim 1,
wherein the displacement suppressing portion is on a peripheral edge of the rear-side end face of the thermal conductor, and includes a flange shape.

3. The light-emitting module according to claim 1,
wherein the displacement suppressing portion includes a tapered shape in which an outer diameter of the thermal conductor decreases in the direction from the rear surface to the mounting surface.

4. The light-emitting module according to claim 3,
wherein the thermal conductor further includes a second displacement suppressing portion that suppresses displacement of the thermal conductor in a second. direction from the mounting surface to the rear surface, and
the second displacement suppressing portion includes a second tapered shape in which the outer diameter of the thermal conductor decreases in the second direction from the mounting surface to the rear surface.

5. The light-emitting module according to claim 1,
wherein the thermal conductor includes a tapered shape portion in which an outer diameter increases in the direction from the rear surface to the mounting surface.

6. The light-emitting module according to claim 1,
wherein the displacement suppressing portion includes a stepped shape in which an outer diameter of the thermal conductor decreases in a stepwise manner in the direction from the rear surface to the mounting surface.

7. The light-emitting module according to claim 1,
wherein the displacement suppressing portion includes a shape in which an outer diameter of the thermal conductor increases and then decreases in the direction from the rear surface to the mounting surface.

8. The light-emitting module according to claim 1,
wherein the displacement suppressing portion includes an outer diameter which is larger than a minimum value of a diameter of the inner wall of the insulating substrate defined by the through hole.

9. The light-emitting module according to claim 1,
wherein the thermal conductor further includes a second displacement suppressing portion that suppresses displacement of the thermal conductor in a direction from the mounting surface to the rear surface.

10. The light-emitting module according to claim 1,
wherein the displacement suppressing portion of the thermal conductor comprises a protrusion between the mounting-side end and the rear-side end, and
a first protruding distance of the protrusion on the rear-side end of the thermal conductor is less than a second protruding distance of the protrusion on the mounting-side end of the thermal conductor.

11. The light-emitting module according to claim 1,
wherein the thermal conductor is joined to the light-emitting element on the mounting surface.

12. The light-emitting module according to claim 1,
wherein the thermal conductor includes at least one spaced portion which faces and is spaced apart from the inner wall of the insulating substrate defined by the through hole, the spaced portion defining a void between the thermal conductor and the insulating substrate.

13. The light-emitting module according to claim 1,
wherein the thermal conductor overlaps with at least a portion of the light-emitting element in a plan view of the insulating substrate.

14. The light-emitting module according to claim 1, further comprising:
a heat equalizing layer thermally connected to the thermal conductor and extending on the rear surface.

15. The light-emitting module according to claim 1,
wherein the thermal conductor is thermally connected to a heat dissipator at the rear-side end face.

16. The light-emitting module according to claim 15, further comprising:
the heat dissipator.

17. A lighting apparatus for a mobile object, comprising:
the light-emitting module according to claim 1.

18. The lighting apparatus for the mobile object according to claim 17,
wherein the thermal conductor is positioned higher in a vertical direction of the mobile object than the light-emitting element.

19. The lighting apparatus for the mobile object according to claim 17, further comprising:
a flow path for flowing a gas around the light-emitting module,
wherein the thermal conductor is positioned further downstream along the flow path than the light-emitting element.

20. A mobile object, comprising:
a headlight, the headlight including the lighting apparatus for the mobile object according to claim 17.
